(19) United States
(12) Patent Application Publication
(10) Pub. No.: US 2010/0171396 A1
(43) Pub. Date: Jul. 8, 2010

(54) PIEZOELECTRIC ACTUATOR, METHOD OF MANUFACTURING THE SAME AND METHOD OF MANUFACTURING A PRINT HEAD

(76) Inventors: Tae-Kyung LEE, Gyeonggi-do (KR); Hwa-Sun LEE, Gyeonggi-do (KR); Tae-Woon CHA, Seoul (KR); Seung-Mo LIM, Gyeonggi-do (KR); Jae-Chang LEE, Gyeonggi-do (KR)

Correspondence Address: Haynes and Boone, LLP;IP Section, 2323 Victory Avenue, SUITE 700, Dallas, TX, 75219, US

(21) Appl. No.: 12/553,030

(22) Filed: Sep. 2, 2009

(30) Foreign Application Priority Data
Jan. 7, 2009 (KR) 2009-0001036

(51) Int. Cl. H01L 41/04; H01L 41/22

(52) U.S. Cl. 310/367; 29/25.35

(57) ABSTRACT

A piezoelectric actuator includes a first electrode layer, a piezoelectric layer and a second electrode layer. The first electrode layer is formed on a vibration plate. The piezoelectric layer is formed on the first electrode layer, the piezoelectric layer comprising piezoelectric particles formed on the surface of a self-assembled monolayer. The second electrode layer is formed on the piezoelectric layer to face the first electrode layer. Thus, a self-assembled monolayer is formed, so that the piezoelectric characteristics of a piezoelectric layer and/or the stiffness of the piezoelectric layer may be increased. Thus, piezoelectric characteristics of the piezoelectric actuator may be enhanced, and the required voltage, which is required to realize a proper deformation amount of the piezoelectric actuator, may be decreased. Moreover, the stiffness of the piezoelectric actuator may be increased, so that the vibration remaining at the piezoelectric actuator may be minimized even though the driving is finished.

### CROSS-REFERENCE TO RELATED APPLICATIONS

This application claims priority under 35 U.S.C. §119 to Korean Patent Application No. 2009-1036, filed on Jan. 7, 2009 in the Korean Intellectual Property Office (KIPO), the contents of which are herein incorporated by reference in their entirety.

### BACKGROUND OF THE INVENTION

1. Field of the Invention

Embodiments of the present invention relate to a piezoelectric actuator, a method of manufacturing the piezoelectric actuator, and a method of manufacturing a print head. More particularly, embodiments of the present invention relate to a piezoelectric actuator for an inkjet print head, a method of manufacturing the piezoelectric actuator, and a method of manufacturing a print head.

2. Description of the Related Art

Generally, an inkjet print head may be classified as either a thermally driven type or a pressure type in accordance with an ink ejection method. In the thermally driven type, a heat source is used to generate a bubble and the ink is ejected onto the paper through the expansive force of the bubble. In the pressure type, a piezoelectric element is transformed by the voltage it receives, and a vibration plate applies pressure to ink in a chamber to eject the ink through a nozzle.

A porous piezoelectric element has low piezoelectric characteristics in comparison with a bulk piezoelectric element. That is, when the same voltage is applied thereto, the deformation amount of the porous piezoelectric element is smaller than that of the bulk piezoelectric element. Thus, when the porous piezoelectric element is used in a piezoelectric actuator, a greater voltage is applied to the porous piezoelectric actuator to eject ink of a proper amount. Thus, when the porous piezoelectric element is used in a piezoelectric actuator, power consumption required to drive the piezoelectric actuator is greater than that needed for a bulk piezoelectric element.

A vibration plate is vibrated by the transformation of a piezoelectric element when the piezoelectric actuator is driven, and the vibration of the piezoelectric actuator and the vibration plate is stopped when the driving of the piezoelectric actuator is stopped. However, even though the driving of the piezoelectric actuator is stopped, the time for stopping the vibration of the piezoelectric actuator and the vibration plate is longer when the stiffness of the piezoelectric actuator is lower. That is, the deformation amount of a piezoelectric actuator is higher when the thickness of the piezoelectric actuator is thinner. A high voltage is required to maintain a proper deformation amount of the piezoelectric actuator when the thickness of the piezoelectric actuator is thicker. A driving of the piezoelectric actuator may be disturbed when the time for stopping the vibration of the piezoelectric actuator is longer. In order to solve the problem, when the thickness of the vibration plate is increased, power consumption required for driving the piezoelectric actuator is increased or the deformation of the vibration plate is decreased, so that electric characteristics of the piezoelectric actuator may be decreased. Thus, the problem of attaining a proper deformation amount of the piezoelectric actuator and the problem of minimizing power consumption may be difficult to solve at the same time.

### SUMMARY OF THE INVENTION

Embodiments of the present invention provide a piezoelectric actuator having improved piezoelectric characteristics and stiffness thereof.

Embodiments of the present invention also provide a method of manufacturing the above-mentioned piezoelectric actuator.

Embodiments of the present invention also provide a method of manufacturing a print head having the above-mentioned piezoelectric actuator.

According to one aspect of the present invention, a piezoelectric actuator includes a first electrode layer, a piezoelectric layer and a second electrode layer. The first electrode layer is formed on a vibration plate. The piezoelectric layer is formed on the first electrode layer, the piezoelectric layer comprising piezoelectric particles formed on the surface of a self-assembled monolayer. The second electrode layer is formed on the piezoelectric layer to face the first electrode layer.

In an embodiment of the present invention, the self-assembled monolayer may include a buffer layer and an overcoat layer.

According to another aspect of the present invention, there is provided a method of manufacturing a piezoelectric actuator. In the method, a first electrode layer, a piezoelectric layer and a second electrode layer are formed on a vibration plate. The first electrode layer is formed on the vibration plate, the piezoelectric layer comprising piezoelectric particles is formed on the first electrode layer, and the second electrode layer is formed on the piezoelectric layer. A self-assembled monolayer is formed on the vibration plate on which the first electrode layer, the piezoelectric layer and the second electrode layer are formed using a self-assembled precursor in a vapor state.

In one embodiment, the self-assembled precursor infiltrates into the piezoelectric layer in order to form the self-assembled monolayer on the surface of each piezoelectric particle.

In another embodiment for the formation of the self-assembled monolayer, a buffer layer that contacts each surface of the piezoelectric particles is formed, and then an overcoat layer may be formed on the buffer layer.

In another embodiment, the self-assembled monolayer is formed on the surface of the second electrode layer.

According to still another aspect of the present invention, there is provided a method of manufacturing a print head. In the method, the first electrode layer is formed on the vibration plate, the piezoelectric layer comprising piezoelectric particles is formed on the first electrode layer, and the second electrode layer is formed on the piezoelectric layer. A printed circuit board (PCB) is electrically connected to the second electrode layer. A self-assembled monolayer is formed on the vibration plate on which the first electrode layer, the piezoelectric layer, the PCB and the second electrode layer are formed using a self-assembled precursor in a vapor state.

According to a method of manufacturing the piezoelectric actuator and a method of manufacturing a print head, a self-assembled monolayer is formed, so that the piezoelectric characteristics of the piezoelectric layer and/or the stiffness of the piezoelectric layer is increased. Thus, the piezoelectric characteristics of the piezoelectric actuator may be enhanced, and the required voltage to realize a proper deformation amount of the piezoelectric actuator may be decreased. Moreover, the stiffness of the piezoelectric actuator may be increased, so that the vibration of the piezoelectric actuator remaining after driving is finished may be reduced.

### BRIEF DESCRIPTION OF THE DRAWINGS

The above and other features and advantages of the present invention will become more apparent by describing in detailed embodiments thereof with reference to the accompanying drawings, in which:

FIG. 1 is a plan view illustrating a portion of a printer head according to Embodiment 1 of the present invention;

FIG. 2 is a cross-sectional view taken along a line I-I′ of FIG. 1;

FIG. 3 is an enlarged cross-sectional view illustrating a portion ‘A’ of FIG. 2;

FIG. 4 is a flowchart showing a method of manufacturing a print head as shown in FIG. 2;

FIGS. 5 to 8 are cross-sectional views illustrating each of the steps shown in FIG. 4;

FIG. 9 is a cross-sectional view illustrating a piezoelectric particle of a self-assembled monolayer according to Embodiment 2 of the present invention;

FIG. 10 is a flowchart showing the step in which the self-assembled monolayer of FIG. 9 is formed;

FIG. 11 is a cross-sectional view of a print head according to Embodiment 3 of the present invention; and

FIG. 12 is an enlarged cross-sectional view illustrating a portion ‘B’ of FIG. 11.

### DETAILED DESCRIPTION OF THE INVENTION

The present invention is described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In the drawings, the same or similar elements are denoted by the same or similar reference numerals even though they are depicted in different figures. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented, rotated 90 degrees or at other orientations, and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized embodiments and intermediate structures of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from an implanted to a non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms, including technical and scientific terms, used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

### Embodiment 1

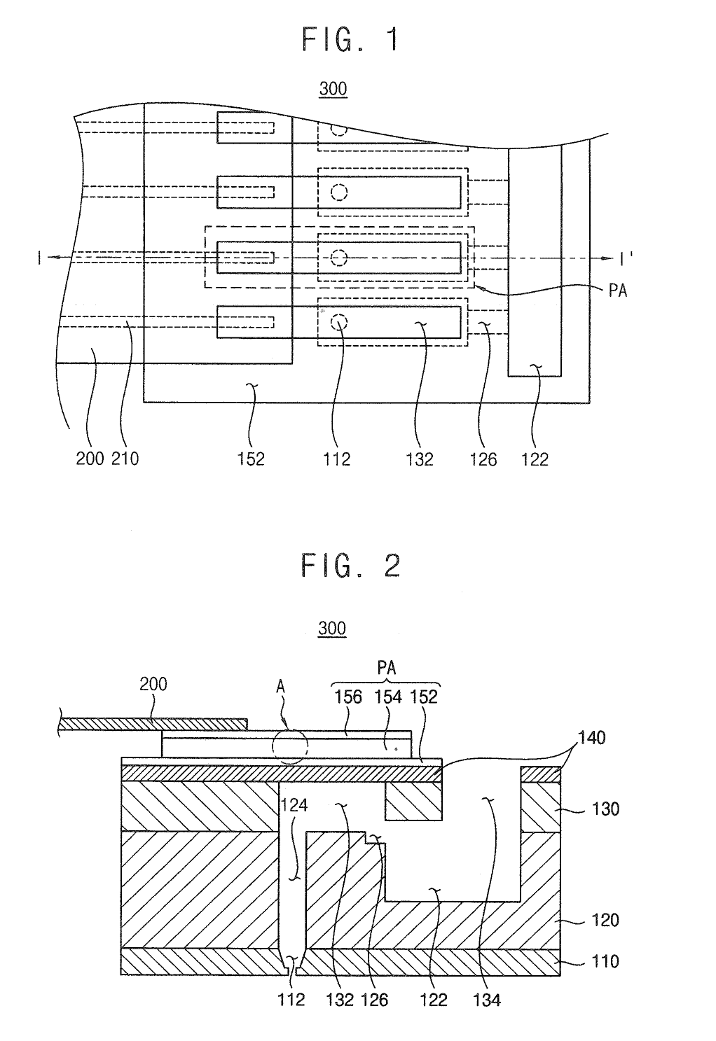

FIG. 1 is a plan view illustrating a portion of a printer head according to Embodiment 1 of the present invention.

FIG. 2 is a cross-sectional view taken along a line I-I′ of FIG. 1.

Referring to FIGS. 1 and 2, a print head 300 according to the present embodiment includes a nozzle plate 110, a first flow path plate 120, a second flow path plate 130, a vibration plate 140 and a plurality of piezoelectric actuators PA. The print head 300 is electrically connected to a power providing part (not shown) providing the piezoelectric actuators PA with power through a printed circuit board (PCB) 200.

The nozzle plate 110, the first path plate 120, the second flow path plate 130 and the vibration plate 140 may be comprised of an amorphous silicon wafer. The nozzle plate 110, the first path plate 120, the second flow path plate 130 and the vibration plate 140 are assembled to form an ink flow path. The ink flow path includes an ink providing path 134, a manifold 122, a restrictor 126, a pressure chamber 132, a damper 124 and a nozzle 112. A plurality of patterns, which are formed on the nozzle plate 110, the first flow plate 120, the second flow path plate 130 and the vibration plate 140, may be formed through a photolithography process.

The manifold 122 may receive ink from the exterior through the ink providing path 134. The manifold 122 may provide the ink to the pressure chamber 132. The manifold 122 may be extended in a first direction on the first flow path plate 120. The manifold 122 may be depressed from an upper surface of the flow path plate 120 to a predetermined depth.

The restrictor 126 is an individual flow path that provides ink to the pressure chamber 132 from a common flow path of the manifold's 122 common flow path. In one example, the restrictor 126 may be depressed to a predetermined depth from an upper surface of the first flow path plate 120. In another example, the restrictor 126 may penetrate the first flow path plate 120 in a vertical direction thereof.

The pressure chamber 132 may vary in pressure in order to eject the ink from the interior of the print head 300 to the exterior of the print head 300. The ink that fills up the manifold 122 may infiltrate the pressure chamber 132 by flowing from the pressure chamber 132 through to the restrictor 126. The pressure of the pressure chamber 132 is varied by applying a voltage to the piezoelectric actuator PA, so that the ink in the pressure chamber 132 may be ejected to the exterior of the print head 300 through the nozzle 112. The pressure chamber 132 may be depressed to a predetermined depth by a lower surface of the second flow path plate 130. The pressure chamber 132 may be formed perpendicular to a first wall surface of the manifold 122. Alternatively, the pressure chamber 132 may be formed perpendicular to two wall surfaces of the manifold 122.

The nozzle 112 may spray the ink in the pressure chamber 132 to the exterior of the print head 300. The nozzle 112 may penetrate the nozzle plate 110 in a perpendicular direction thereof. A surface reforming layer 160 (referred to in FIG. 8) may be formed on an opposite surface of the first flow path plate 120 than the nozzle plate 110. The surface reforming layer 160 may prevent the ink from remaining in the nozzle 112 when the ink is ejected to the exterior of the print head 300 through the nozzle 112.

The ink flow path may further include a damper 124. The damper 124 may be disposed between the pressure chamber 132 and the nozzle 112. The damper 124 may concentrate the force generated in the pressure chamber 132 by the piezoelectric actuator PA toward the nozzle 122 and may also buffer a sudden pressure variation.

Each piezoelectric actuator PA is formed on the vibration plate 140. The piezoelectric actuator PA is formed on the vibration plate 140 in a space that corresponds to the pressure chamber 132. The piezoelectric actuator PA provides the driving force for spraying the ink. The piezoelectric actuator PA includes a first electrode layer 152 that is a common electrode, a piezoelectric layer 154 that is deformed in accordance with a voltage, and a second electrode layer 156 that is a driving electrode.

The first electrode layer 152 may be formed on the entire surface of the vibration plate 140. The second electrode layer 156 may be formed on the piezoelectric layer 154. Each of the first and second electrode layers 152 and 156 may include one or two conductive metal materials. For example, each of the first and second electrode layers 152 and 156 may be formed in a double layer that includes a titanium layer and a platinum layer.

The PCB 200 includes a plurality of signal lines 210 that transfer the exterior voltage to the piezoelectric actuator PA. Each of the signal lines 210 may be electrically connected to the piezoelectric actuator PA. The signal line 210 directly contacts the second electrode layer 156, so that the PCB 200 may electrically connect to the piezoelectric actuator PA.

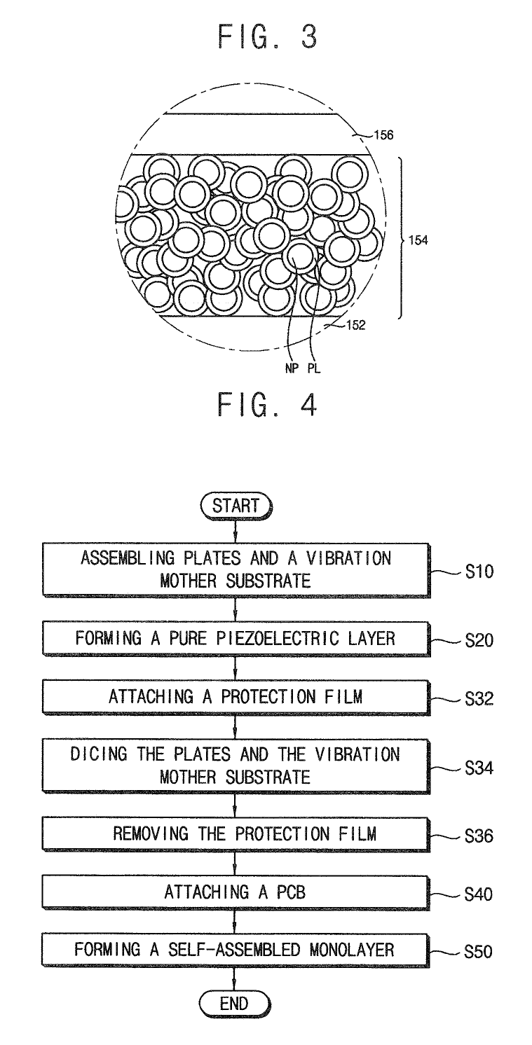

FIG. 3 is an enlarged cross-sectional view illustrating a portion ‘A’ of a FIG. 2.

Referring to FIG. 3, the piezoelectric layer 154 may be formed between the first electrode layer 152 and the second electrode layer 156. The piezoelectric layer 154 may be disposed at a position corresponding to the pressure chamber 132. The piezoelectric layer 154 is deformed by a voltage, so that the volume of the pressure chamber 132 may be varied.

The piezoelectric layer 154 includes piezoelectric particles NP. Each of the piezoelectric particles NP includes self-assembled monolayer PL which surrounds a surface thereof. When a predetermined voltage is applied to the piezoelectric layer 154, the deformation amount of the piezoelectric actuator PA including the piezoelectric layer 154 is substantially greater than the deformation amount of the piezoelectric actuator (not shown) including a conventional piezoelectric layer but not including the self-assembled monolayer PL. Thus, the voltage, that is required to realize the proper deformation amount of the piezoelectric layer 154, may be decreased, so that power consumption for driving the piezoelectric actuator PA may be decreased. Moreover, the stiffness of the piezoelectric actuator PA including the piezoelectric layer 154 may be greater than the stiffness of the piezoelectric actuator including a conventional piezoelectric layer.

The piezoelectric particles NP include, for example, lead zirconate titanate (PZT), lead scandium tantalate (PST), quartz, lead titanate (PbTiO₃), tin titanate (SnTiO₃), and/or barium titanate (BaTiO₃). The self-assembled monolayer PL may include a xylene composition. The xylene composition may be formed by the self-assembly of a precursor in a vapor state. The self-assembled precursor includes, for example, 1,2-bis(trichlorosilyl)ethane (BTCSE), and/or perfluorodecyltrichlorosilane (FDTS).

Hereinafter, the increase in the deformation amount and stiffness of a piezoelectric actuator in accordance with the present embodiment will be explained.

Four piezoelectric actuators were formed on a plate having a thickness of about 13 μm. The four piezoelectric actuators had a PZT piezoelectric layer that extended along a first direction by about 3,000 μm. A voltage of about 35 volts (V) having a frequency of about 2 kHz was applied to the four piezoelectric actuators, and then initial deformation amounts and resonance frequencies corresponding to the four piezoelectric actuators were measured. These measurements will be shown in the following Tables 1 and 2.

BTCSE was applied to the first piezoelectric actuator to form a self-assembled monolayer having a thickness of about 100 Å on the piezoelectric particles of a PZT piezoelectric layer. A voltage of about 35 V with a frequency of about 2 kHz was applied to the self-assembled monolayer, and then the final deformation amount and the final resonance frequency were measured. These measurements will be shown in the following Table 1.

FDTS was applied to the second piezoelectric actuator to form a self-assembled monolayer having a thickness of about 100 Å on the piezoelectric particles of a PZT piezoelectric layer. A voltage of about 35 V with a frequency of about 2 kHz was applied to the self-assembled monolayer, and then a final deformation amount and a final resonance frequency were measured. These measurements are shown in the following Table 1.

TABLE 1

| | Initial | Final | Variation | Initial | Final |
|---|---|---|---|---|---|
| | Deformation | Deformation | Increasing | Resonance | Resonance |
| | Amount | Amount | Ratio | Frequency | Frequency |
| First | −53.96 nm | −65.76 nm | about 22% | 600 kHz | 605 kHz |
| piezo- | | | | | |
| electric | | | | | |
| actuator | | | | | |
| Second | −50.99 nm | −56.75 nm | about 11% | 604 kHz | 607 kHz |
| piezo- | | | | | |
| electric | | | | | |
| actuator | | | | | |

BTCSE was applied to each of the third and fourth piezoelectric actuators twice to form a self-assembled monolayer on piezoelectric particles of a PZT piezoelectric layer. A voltage of about 35 V with a frequency of about 2 kHz was applied to the self-assembled monolayer, and then the final deformation amount and the final resonance frequency were measured. The measurements are shown in the following Table 2.

TABLE 2

| | Initial | | | | |
|---|---|---|---|---|---|
| | De- | First | Second | Initial | Final |
| | formation | Deformation | Deformation | Resonance | Resonance |
| | Amount | Amount | Amount | Frequency | Frequency |
| Third | −32.51 nm | −42.88 nm | −43.28 nm | 730 kHz | 740 kHz |
| piezo- | | | | | |
| electric | | | | | |
| actuator | | | | | |
| Fourth | −33.47 nm | −41.41 nm | −43.23 nm | 728 kHz | 738 kHz |
| piezo- | | | | | |
| electric | | | | | |
| actuator | | | | | |

In Tables 1 and 2, when the center of the length direction of the PZT piezoelectric layer is at ‘0’, the “deformation amount” represents an average value of distance in which the PZT piezoelectric layer is bent in the direction of gravity from about +1,000 μm to about −1,000 μm from the center. That is, when the PZT piezoelectric layer is parallel to the ground surface on which a print head is disposed, the deformation amount may be defined as an average of the distance of deformation toward the ground surface. The deformation amount may be a negative value. When the absolute value of the average is increased, the deformation amount is increased. When an absolute value of the average is decreased, the deformation amount is decreased.

Referring to Table 1, the initial deformation amount of the first piezoelectric actuator is about −53.96 nm. The final deformation amount of the first piezoelectric actuator is about −65.76 nm. In the first piezoelectric actuator, the final deformation amount is increased by about 22% in comparison with the initial deformation amount. That is, a self-assembled monolayer is formed by BTCSE so that the deformation amount of the first piezoelectric actuator is increased.

The initial deformation amount of the second piezoelectric actuator is about −50.99 nm. The final deformation amount of the second piezoelectric actuator is about −56.75 nm. In the second piezoelectric actuator, the final deformation amount is increased about 11% in comparison with the initial deformation amount. That is, the second piezoelectric actuator has a self-assembled monolayer formed by FDTS, so that the deformation amount is increased.

Moreover, the initial resonance frequency of the first piezoelectric actuator is about 600 kHz, and the final resonance frequency of the first piezoelectric actuator is about 605 kHz. The initial resonance frequency of the second piezoelectric actuator is about 605 kHz, and the final resonance frequency of the second piezoelectric actuator is about 607 kHz. As the self-assembled monolayer is formed, the resonance frequency is increased. Thus, the stiffness of the PZT piezoelectric layer is increased by the addition of the self-assembled monolayer.

Referring to Table 2, the initial deformation amount of the third piezoelectric actuator is about −32.51 nm. The first deformation amount in which BTCSE is initially applied to the third piezoelectric actuator is about −42.88 nm, and the second deformation amount in which BTCSE is again applied to the third piezoelectric actuator is about −42.28 nm. When BTCSE is deposited on the third piezoelectric actuator the second time, the deformation amount is greater when compared to the first deformation amount and initial depositing of BTCSE. In the third piezoelectric actuator, the difference between the initial deformation amount and the first deformation amount is greater than the difference between the first deformation amount and the second deformation amount.

The initial deformation amount of the fourth piezoelectric actuator is about −33.47 nm. The first deformation amount in which BTCSE is initially applied to the fourth piezoelectric actuator is about −41.41 nm, and the second deformation amount in which BTCSE is again applied to the fourth piezoelectric actuator is about −43.23 nm. When the BTCSE is deposited on the fourth piezoelectric actuator the second time, the deformation amount is greater when compared to the first deformation amount and initial depositing of BTCSE. In the fourth piezoelectric actuator, the difference between the initial deformation amount and the first deformation amount is greater than a difference between the first deformation amount and the second deformation amount.

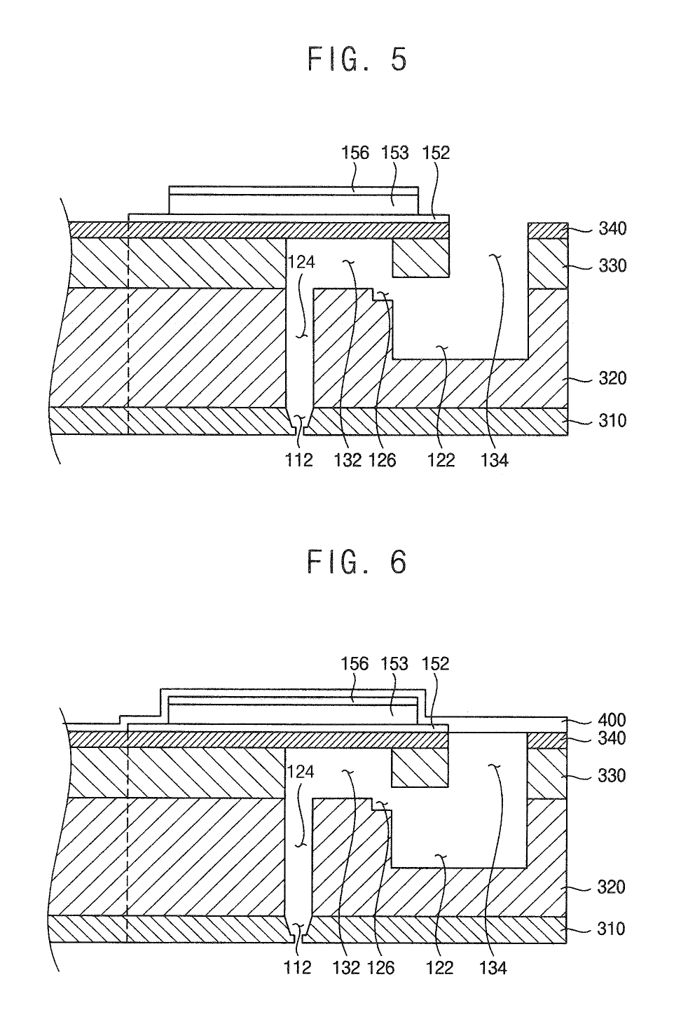

Hereinafter, a method of manufacturing a print head as shown in FIG. 2 will be explained in detail with reference to the flowchart of FIG. 4 and the following FIGS. 5 to 8.

FIG. 3 is an enlarged cross-sectional view illustrating a portion ‘A’ of a FIG. 2. FIGS. 5 to 8 are cross-sectional views illustrating each of the steps shown in FIG. 4.

Referring to FIGS. 4 and 5, a nozzle mother substrate 310, a first flow path mother substrate 320, a second flow path mother substrate 330 and a vibration mother substrate 340 are assembled together (step S10).

The nozzle mother substrate 310 corresponds to the nozzle plate 110, the first flow path mother substrate 320 corresponds to the first flow path plate 120, and the second flow path mother substrate 320 corresponds to the second flow path plate 130. The vibration mother substrate 340 corresponds to the vibration plate 140. The nozzle mother substrate 310, the first flow path mother substrate 320, the second flow path mother substrate 330 and the vibration mother substrate 340 are assembled with each other may be divided into the nozzle plate 110, the first flow path plate 120, the second flow path plate 130 and the vibration plate 140 through a dicing process.

The nozzle mother substrate 310, the first flow path mother substrate 320, the second flow path mother substrate 330 and the vibration mother substrate 340 form the ink flow path including the ink providing path 134, the manifold 122, the restrictor 126, the pressure chamber 132, the damper 124 and the nozzle 112.

Then, a pure piezoelectric layer 153 is formed on the vibration mother substrate 340 (step S20).

For example, the first electrode layer 152 is formed on the vibration mother substrate 340. The first electrode layer 152 may be formed on a whole surface of the vibration mother substrate 340.

The pure piezoelectric layer 153 is formed on the first electrode layer 152. The pure piezoelectric layer 153 includes piezoelectric particles NP. The pure piezoelectric layer 153 may be substantially the same as the piezoelectric layer 154 of FIG. 2 except that the self-assembled monolayer PL is formed on each of the piezoelectric particles NP. The piezoelectric particles NP may include, for example, PZT, PST, quartz, lead titanate (PbTiO₃), tin titanate (SnTiO₃), and/or barium titanate (BaTiO₃).

The second electrode layer 156 is formed on the vibration mother substrate 340 on which the pure piezoelectric layer 153 is formed. The second electrode layer 156 is formed at an area where the pure piezoelectric layer 153 is formed by patterning a metal thin film and forming it on the whole surface of the vibration mother substrate 340.

Referring to FIGS. 4 and 6, a protection film 400 is attached to the vibration mother substrate 340 on which the first electrode layer 152, the pure piezoelectric layer 153 and the second electrode layer 156 are formed (step S32).

The protection film 400 may be attached to the whole surface of the vibration mother substrate 340 on which the first electrode layer 152, the pure piezoelectric layer 153 and the second electrode layer 156 are formed. The protection film 400 prevents silicon particles, which are formed by dicing of the nozzle mother substrate 310, the first flow path mother substrate 320, the second flow path mother substrate 330 and the vibration mother substrate 340, from flowing into the ink flow path. Moreover, the protection film 400 prevents the first electrode layer 152, the pure piezoelectric layer 153 and the second electrode layer 156 from deteriorating due to ultraviolet (UV) light in the dicing process.

When the protection film 400 is attached to the vibration mother substrate 340, the nozzle mother substrate 310, the first flow path mother substrate 320, and the second flow path mother substrate 340 that were assembled together are diced. (step S34).

Therefore, the first electrode layer 152, the pure piezoelectric layer 153 and the second electrode layer 156 are not damaged, and the nozzle plate 110, the first flow path plate 120, the second flow path plate 130 and the vibration plate 140 are formed.

After the dicing process is finished, the protection film is removed (step S36).

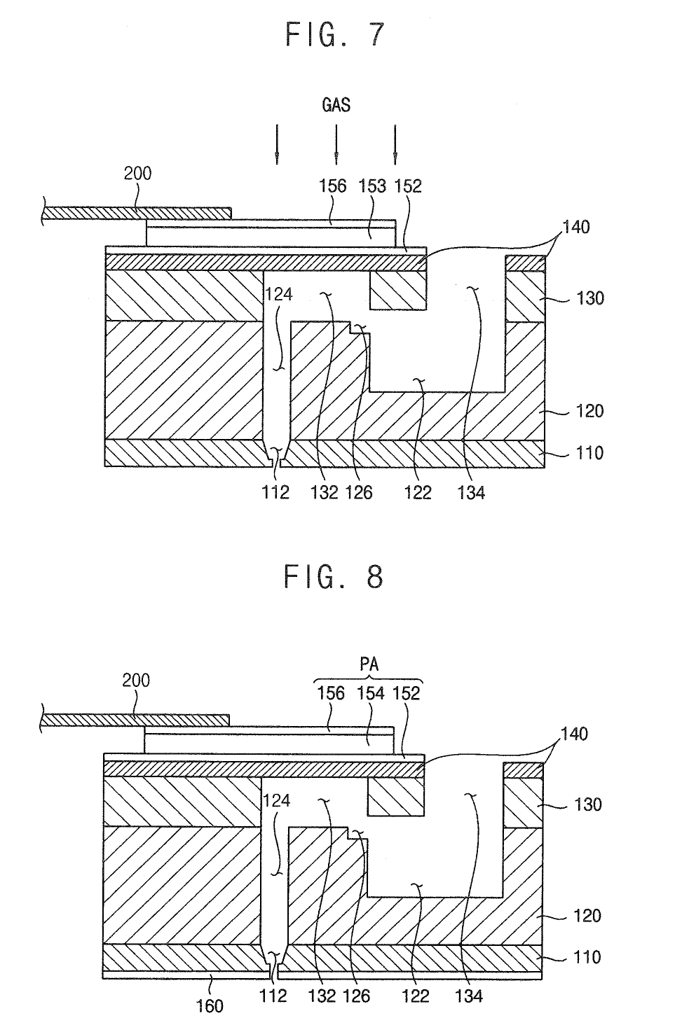

Referring to FIGS. 4 and 7, the PCB 200 is attached to the second electrode layer 156 that is exposed when the protection film 400 is removed, and a self-assembled precursor in a vapor state is provided (step S40).

Even though the protection film 400 is removed in a previous process, the PCB 200 remains attached and prevents the area of the second electrode layer 156 in contact with the PCB 200 from being polluted by the self-assembled precursor. The self-assembled precursor includes, for example, BTCSE, and/or FDTS.

Referring to FIGS. 4 and 8, the self-assembled monolayer PL is formed on the pure piezoelectric layer 153 that receives the self-assembled precursor (step S50).

The self-assembled precursor forms one thin film through a self-assembly reaction during a predetermined time in a vacuum state. That is, the self-assembled precursor forms the self-assembled monolayer PL through a self-assembly reaction. For example, the self-assembled precursor infiltrates the interior of the pure piezoelectric layer 153 in a vapor state, and the self-assembled precursor which infiltrates into the interior of the pure piezoelectric layer 153 may form a self-assembled monolayer PL on a surface of the piezoelectric particle NP through the self-assembly reaction.

In the process of forming the self-assembled monolayer PL, a surface reforming layer 160 may be formed on a surface of the nozzle plate 110. The nozzle plate 110, the first flow path plate 120, the second flow path plate 130 and the vibration plate 140 all may include a silicon material. Each surface of the nozzle plate 110, the first flow path plate 120, the second flow path plate 130 and the vibration plate 140 may include a silicon oxide (SiO₂). For example, each of the nozzle plate 110, the first flow path plate 120, the second flow path plate 130 and the vibration plate 140 may be formed from a silicon wafer, and the silicon wafer is heat treated so that a silicon oxide is formed on a surface of the silicon wafer. Thus, each surface of the nozzle plate 110, the first flow path plate 120, the second flow path plate 130 and the vibration plate 140 have a high affinity with ink. However, the affinity of the surface reforming layer 160 with ink is lower than the other surfaces, so that the ink may be easily ejected from the nozzle 112 by the surface reforming layer 160.

The self-assembled monolayer PL may be formed in a process during the formation of the surface reforming layer 160, so that the piezoelectric layer 154 may be easily formed from the pure piezoelectric layer 153 even through an additional independent process is not added.

### Embodiment 2

The method of forming a print head according to the present embodiment is substantially the same as the print head of Embodiment 1 except for the formation of the self-assembled monolayer. Thus, only a detailed description of the method of forming the self-assembled monolayer will be described.

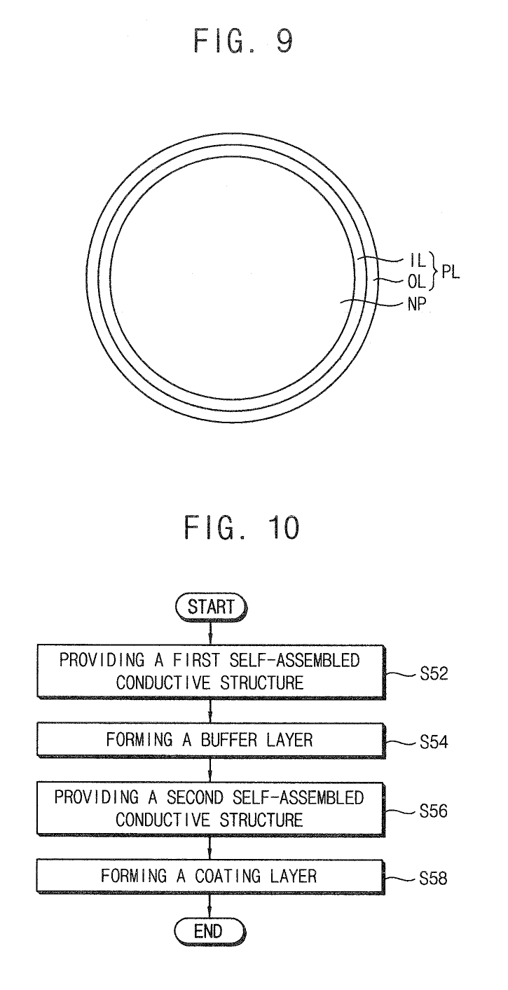

FIG. 9 is a cross-sectional view illustrating a piezoelectric particle of the self-assembled monolayer according to Embodiment 2 of the present invention.

Referring to FIG. 9, the self-assembled monolayer PL which surrounds the surface of the piezoelectric particles NP includes a buffer layer IL and an overcoat layer OL.

The buffer layer IL is a layer directly contacting the surface of the piezoelectric particles NP. The buffer layer IL is interposed between the piezoelectric particles NP and the overcoat layer OL to enhance the adhesive force of the piezoelectric particles NP and the overcoat layer OL. The self-assembled precursor that forms the buffer layer IL may include BTCSE.

The overcoat layer OL is formed on the buffer layer IL to substantially enhance the deformation amount and the stiffness of the piezoelectric actuator including the piezoelectric particles NP. The self-assembled precursor that forms the overcoat layer OL may include FDTS.

The method of manufacturing a print head according to the present embodiment is substantially the same as the method of manufacturing the print head according to Embodiment 1 except for the step of forming the self-assembled monolayer. Thus, a detailed description of the method of forming the print head will be omitted, and the step of forming the self-assembled monolayer according to the present embodiment will be explained with reference to the following FIGS. 7, 9 and 10.

FIG. 10 is a flowchart showing the step in which a self-assembled monolayer of FIG. 9 is formed.

Referring to FIGS. 7 and 10, the nozzle plate 110, the first flow path plate 120, the second flow path plate 130 and the vibration plate 140 are assembled. The first electrode layer 152, the pure piezoelectric layer 153 and the second electrode layer 156 are formed on the vibration plate 140.

A PCB 200 is attached to the second electrode layer 156 to electrically connect the second electrode layer 156 and the PCB 200.

Then, a first self-assembled precursor is provided to the pure piezoelectric layer 153 that contains the piezoelectric particle NP (step S52).

The first self-assembled precursor is infiltrated into the pure piezoelectric layer 153 to form the buffer layer IL on the surface of the piezoelectric particle NP (step S54).

Then, a second self-assembled precursor is provided to the pure piezoelectric layer 153 surrounding the buffer layer IL (step S56).

The second self-assembled precursor is infiltrated into the pure piezoelectric layer 153 to form the overcoat layer OL on the surface of the buffer layer IL (step S58).

Hereinafter, an increase in the deformation amount and the stiffness of a piezoelectric actuator according to the present embodiment will be described.

A fifth piezoelectric actuator having a PZT piezoelectric layer that is extended along a first direction by about 3,000 μm was formed on a plate having a thickness of about 13 μm. A voltage of about 35 V having a frequency of about 2 kHz was applied to the fifth piezoelectric actuators, and then the initial deformation amount and the resonance frequency corresponding to the fifth piezoelectric actuator were measured. The above measurements are shown in the following Table 3.

BTCSE was applied to the fifth piezoelectric actuator to form a buffer layer and FDTS was applied to the fifth piezoelectric actuator to form an overcoat layer, and then a voltage of about 35 V with a frequency of about 2 kHz was applied to the self-assembled monolayer including the buffer layer and the overcoat layer. Then, the final deformation amount and the final resonance frequency after the self-assembled monolayer was formed were measured. The above measurements are shown in Table 3.

TABLE 3

| | Initial | Final | Variation | Initial | Final |
|---|---|---|---|---|---|
| | Deformation | Deformation | Increasing | Resonance | Resonance |
| | Amount | Amount | Ratio | Frequency | Frequency |
| Fifth | −52.51 nm | −69.55 nm | about 32% | 599 kHz | 605 kHz |
| piezo- | | | | | |
| electric | | | | | |
| actuator | | | | | |

In Table 3, when the center of the length direction of the PZT piezoelectric layer is at ‘0’, the “deformation amount” represents an average value of the distance in which the PZT piezoelectric layer is bent in a the direction of gravity from about +1,000 μm to about −1,000 μm from the center. That is, when the PZT piezoelectric layer is parallel to the ground surface on which a print head is disposed, the deformation amount may be defined by an average of the increased distance of deformation toward the ground surface. The deformation amount may be a negative value. When the absolute value of the average is increased, the deformation amount is increased. When an absolute value of the average is decreased, the deformation amount is decreased.

Referring to Table 3, the initial deformation amount of the fifth piezoelectric actuator is about −52.51 nm. The final deformation amount of the fifth piezoelectric actuator is about −69.55 nm. In the fifth piezoelectric actuator, the final deformation amount is increased by about 32% in comparison with the initial deformation amount. That is, the self-assembled monolayer formed by BTCSE increases the deformation amount of the fifth piezoelectric actuator. Moreover, the initial resonance frequency of the fifth piezoelectric actuator is about 599 kHz, and the final resonance frequency of the fifth piezoelectric actuator is about 605 kHz. As the self-assembled monolayer is formed, the resonance frequency is increased. Thus, the stiffness of the PZT piezoelectric layer is increased by the addition of the self-assembled monolayer.

The deformation amount and stiffness of the fifth piezoelectric actuator are greater in comparison with those of the first and second piezoelectric actuators.

Hereinafter, a deformation amount compensation effect, an increasing deformation amount and an increasing stiffness of a piezoelectric actuator according to the present embodiment will be explained.

A sixth piezoelectric actuator was formed on a plate having a thickness of about 13 μm. The sixth piezoelectric actuator had a PZT piezoelectric layer that extended along a first direction by about 3,000 μm. A voltage of about 35 V having a frequency of about 2 kHz was applied to the sixth piezoelectric actuator, and the deformation amount of the sixth piezoelectric actuator was measured. The above measurement is shown in Table 4.

A seventh piezoelectric actuator was formed on a plate having a thickness of about 18 μm. The sixth piezoelectric actuator had a PZT piezoelectric layer that extended along a first direction by about 3,000 μm. A voltage of about 35 V having a frequency of about 2 kHz was applied to the seventh piezoelectric actuator, and the deformation amount of the seventh piezoelectric actuator was measured. The above measurement is shown in Table 4.

An eighth piezoelectric actuator was formed on a plate having a thickness of about 18 μm. The eighth piezoelectric actuator had a PZT piezoelectric layer that extended along a first direction by about 3,000 μm. A buffer layer was formed by applying BTCSE, and an overcoat layer was formed by applying FDTS. Then, a voltage of about 35 V having a frequency of about 2 kHz was applied to the seventh piezoelectric actuator, and the deformation amount of the eighth piezoelectric actuator was measured. The above measurement is shown in Table 4.

TABLE 4

| | Deformation amount |
|---|---|
| Sixth piezoelectric actuator | −87.12 nm |
| Seventh piezoelectric actuator | −69.00 nm |
| Eighth piezoelectric actuator | −82.89 nm |

In Table 4, when the center of the length direction of the PZT piezoelectric layer is at ‘0’, the “deformation amount” represents the average value of the distance in which the PZT piezoelectric layer is bent in the direction of gravity from about +1,000 μm to about −1,000 μm interval from the center. That is, when the PZT piezoelectric layer is parallel to the ground surface on which a print head is disposed, the deformation amount is defined by the average of the distance of deformation toward the ground surface. The deformation amount may be a negative value. When the absolute value of the average is increased, the deformation amount is increased. When an absolute value of the average is decreased, the deformation amount is decreased.

Referring to Table 4, the deformation amount of the sixth piezoelectric actuator is about 87.12 nm, and the deformation amount of the seventh piezoelectric actuator is about 69.00 nm. The piezoelectric layers of the sixth and seventh piezoelectric actuators are identical to each other; however, the deformation amount is smaller when the thickness of the vibration plate is thicker. The deformation amount of the sixth piezoelectric actuator is identical to that of the eighth piezoelectric actuator. That is, a self-assembled monolayer was formed even though the vibration plate of the eighth piezoelectric actuator was thicker. The deformation amount of the eighth piezoelectric actuator may be compensated to a deformation amount equal to that of the sixth piezoelectric actuator.

The self-assembled monolayer PL is formed, so that the deformation amount and stiffness of the piezoelectric actuator PA are increased. Thus, the required voltage, which is required to realize the proper deformation amount of the piezoelectric actuator PA, may be decreased. Moreover, the stiffness may be increased, so that a vibration remaining at the piezoelectric actuator PA may be minimized even though the driving is finished.

### Embodiment 3

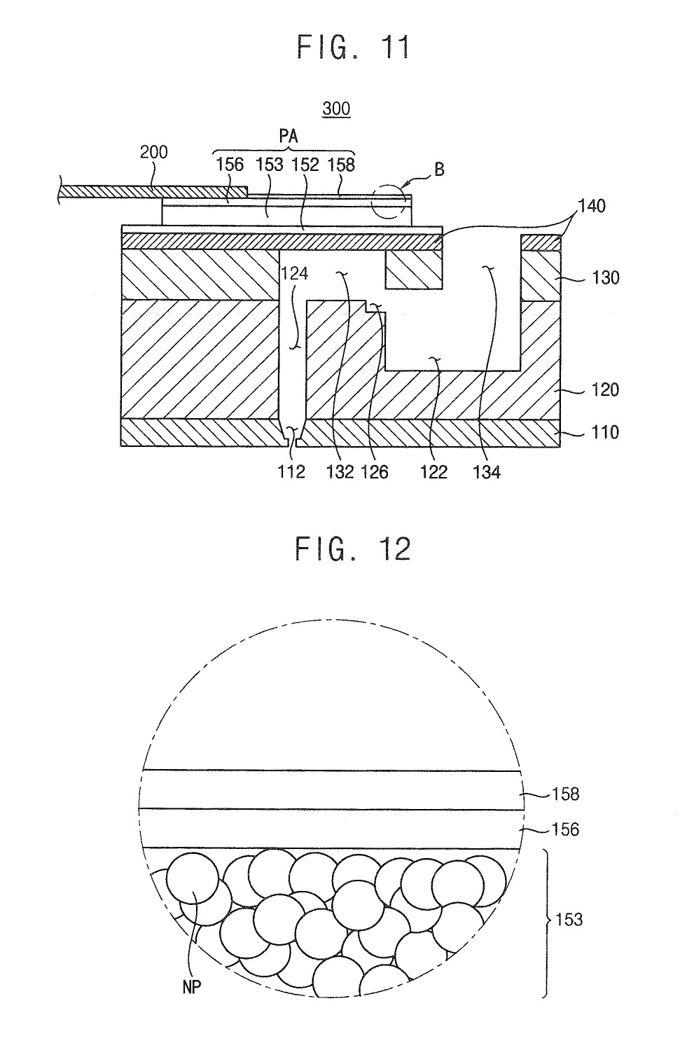

FIG. 11 is a cross-sectional view of a print head according to Embodiment 3 of the present invention.

In FIG. 11, the method of forming a print head 300 according to the present embodiment is substantially the same as the print head of FIGS. 1 and 2 except for the formation of the piezoelectric actuator PA. Thus, only a detailed description of the formation of the piezoelectric actuator will be described.

Referring to FIG. 11, a print head 300 according to the present embodiment includes a nozzle plate 110, a first flow path plate 120, a second flow plate 130, a vibration plate 140 and a plurality of piezoelectric actuators PA. The print head 300 is electrically connected to a voltage providing part (not shown) providing the piezoelectric actuators PA with a voltage through the PCB 200.

Each of the piezoelectric actuators PA is formed on the vibration plate 140. The piezoelectric actuator PA includes a first electrode layer 152 that is a common electrode, a pure piezoelectric layer 154 formed in accordance with a particular voltage, a second electrode layer 156 that is a driving electrode, and a self-assembled monolayer 158 formed on the second electrode layer 156.

The first electrode layer 152 may be formed on the whole surface of the vibration plate 140. The second electrode layer 156 may be formed on the piezoelectric layer 154. Each of the first and second electrode layers 152 and 156 may include one or two conductive metal materials. For example, each of the first and second electrode layers 152 and 156 may be formed in a double layer including a titanium layer and a platinum layer.

FIG. 12 is an enlarged cross-sectional view illustrating the portion ‘B’ of FIG. 11.

Referring to FIG. 12, the pure piezoelectric actuator 152 includes piezoelectric particles NP. The piezoelectric particles NP may be, for example, PZT, PST, quartz, lead titanate (PbTiO₃), tin titanate (SnTiO₃), and/or barium titanate (BaTiO₃).

The self-assembled monolayer 158 is formed on the second electrode layer 156. The self-assembled monolayer 158 increases the stiffness of the piezoelectric actuator PA without decreasing the deformation amount of the piezoelectric actuator PA. That is, the stiffness of the piezoelectric actuator PA including the self-assembled monolayer 158 is greater than the stiffness of the piezoelectric actuator including a conventional piezoelectric layer (not shown).

Hereinafter, increasing the stiffness of a piezoelectric actuator according to the present embodiment will be described.

A ninth piezoelectric actuator was formed on a plate having a thickness of about 13 μm. The ninth piezoelectric actuator has a PZT piezoelectric layer that extends along a first direction by about 3,000 μm. A voltage of about 35 V having a frequency of about 2 kHz was applied to the ninth piezoelectric actuator, and then the initial deformation amount and the resonance frequency of the ninth piezoelectric actuator was measured. The above measurements are shown in Table 5.

Then, xylene was applied to the ninth piezoelectric actuator to form a self-assembled monolayer having a parylene. A voltage of about 35 V with a frequency of about 2 kHz was applied to the self-assembled monolayer, and then the final deformation amount and the final resonance frequency of the ninth piezoelectric actuator was measured. The above measurements are shown in Table 5.

TABLE 5

| | Initial | Final | Initial | Final |
|---|---|---|---|---|
| | Deformation | Deformation | Resonance | Resonance |
| | Amount | Amount | Frequency | Frequency |
| Ninth | −51.06 nm | −52.02 nm | 623 kHz | 634 kHz |
| piezoelectric | | | | |
| actuator | | | | |

In Tables 5, when the center of the length direction of the PZT piezoelectric layer is at ‘0’, the “deformation amount” represents the average value of the distance in which the PZT piezoelectric layer is bent in the direction of gravity from about +1,000 μm to about −1,000 μm from the center. That is, when the PZT piezoelectric layer is parallel to the ground surface on which a print head is disposed, the deformation amount may be defined as the average of the distance of deformation toward the ground surface. The deformation amount may be a negative value. When the absolute value of the average is increased, the deformation amount is increased. When the absolute value of the average is decreased, the deformation amount is decreased.

Referring to Table 5, the initial deformation amount of the ninth piezoelectric actuator is about −51.06 nm, and the final deformation amount of the ninth piezoelectric actuator is about −52.02 nm. The initial resonance frequency of the ninth piezoelectric actuator is about 623 kHz, and the final resonance frequency of the ninth piezoelectric actuator is about 634 kHz. The final deformation amount doesn't increase much compared to the initial deformation amount. The resonance frequency is increased even though the ninth piezoelectric actuator includes the self-assembled monolayer. That is, the self-assembled monolayer increases the stiffness of the ninth piezoelectric actuator without decreasing the deformation amount of the ninth piezoelectric actuator.

The final deformation amount of the first piezoelectric actuator is about −65.76 nm. In the first piezoelectric actuator, the final deformation amount is increased about 22% in comparison with the initial deformation amount. That is, a self-assembled monolayer formed by BTCSE increases the deformation amount of the first piezoelectric actuator.

A method of manufacturing a print head according to another embodiment of the present invention is substantially the same as the method of manufacturing the print head of FIGS. 4 to 8 except for the kind of self-assembled precursor of FIG. 7. Thus, a detailed description of the method of manufacturing the print head will be omitted.

Referring to FIGS. 7 and 11, the self-assembled precursor is provided on the vibration plate 140 on which the first electrode layer 152, the pure piezoelectric layer 153 and the second electrode layer 156 are formed in a vacuum state. The self-assembled precursor may include xylene, for example.

Xylene is self-assembled during a predetermined time to form parylene on the second electrode layer 156. Thus, the self-assembled monolayer 158 including the parylene may be formed on the second electrode layer 156.

In the formation process of the self-assembled monolayer 158, xylene is self-assembled on the surface of the nozzle plate 110 so that the surface reforming layer 160 (see FIG. 8) may be formed on a surface of the nozzle plate 110.

According to the present invention, the self-assembled monolayer is formed, so that piezoelectric characteristics of a piezoelectric layer and/or the stiffness of the piezoelectric layer is increased. That is, the deformation amount and the stiffness of the piezoelectric actuator are increased. Thus, the required voltage, which is required to realize a proper deformation amount of the piezoelectric actuator PA, is decreased. Moreover, the stiffness is increased, so that the vibration remaining at the piezoelectric actuator PA is minimized even though the driving is finished.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A piezoelectric actuator, comprising:
a first electrode layer formed on a vibration plate;
a piezoelectric layer formed on the first electrode layer, the piezoelectric layer including piezoelectric particles formed on a surface of a self-assembled monolayer; and
a second electrode layer formed on the piezoelectric layer.

2. The piezoelectric actuator of claim 1, wherein the self-assembled monolayer comprises:
a buffer layer formed to contact each surface of the piezoelectric particles; and
an overcoat layer formed on the buffer layer.

3. The piezoelectric actuator of claim 1, wherein the self-assembled monolayer comprises a compound comprising xylene or xylene-containing groups.

4. The piezoelectric actuator of claim 3, wherein the self-assembled monolayer comprises at least one of the following self-assembled precursors in a vapor state: 1,2-bis(trichlorosilyl)ethane (BTCSE) and/or perfluorodecyltrichlorosilane (FDTS).

5. The piezoelectric actuator of claim 1, wherein the thickness of the vibration plate is about 10 μm to about 20 μm.

6. The piezoelectric actuator of claim 1, wherein the self-assembled monolayer is formed on the second electrode layer.

7. The piezoelectric actuator of claim 6, wherein the self-assembled monolayer comprises a parylene.

8. A method of manufacturing a piezoelectric actuator, the method comprising:
forming a first electrode layer, on a vibration plate,
forming a piezoelectric layer including piezoelectric particles on the first electrode layer;
forming a second electrode layer on the piezoelectric layer; and
forming a self-assembled monolayer on the vibration plate using a self-assembled precursor in a vapor state.

9. The method of claim 8, wherein forming the self-assembled monolayer comprises:
infiltrating the self-assembled precursor into the piezoelectric layer in order to form the self-assembled monolayer on the surface of each piezoelectric particle.

10. The method of claim 9, wherein forming the self-assembled monolayer comprises:
forming a buffer layer that contacts each surface of the piezoelectric particles; and
forming an overcoat layer on the buffer layer.

11. The method of claim 10, wherein 1,2-bis(trichlorosilyl)ethane (BTCSE) is self-assembled when the buffer layer is formed.

12. The method of claim 10, wherein perfluorodecyltrichlorosilane (FDTS) is self-assembled when the overcoat layer is formed.

13. The method of claim 8, wherein the self-assembled monolayer is formed on a surface of the second electrode layer.

14. The method of claim 8, wherein the self-assembled monolayer comprises at least one of 1,2-bis(trichlorosilyl)ethane (BTCSE), perfluorodecyltrichlorosilane (FDTS) and/or xylene.

15. A method of manufacturing a print head, the method comprising:
forming a first electrode layer, on a vibration plate,
forming a piezoelectric layer including piezoelectric particles on the first electrode layer;
forming a second electrode layer on the piezoelectric layer;
electrically connecting a printed circuit board (PCB) to the second electrode layer; and
forming a self-assembled monolayer on the vibration plate using a self-assembled precursor in a vapor state.

16. The method of claim 15, wherein the self-assembled monolayer is formed on at least one surface of the piezoelectric particles and on a surface of the second electrode layer.

17. The method of claim 15, wherein the vibration plate is assembled with a nozzle plate on which a nozzle is formed in an area corresponding to a portion of the piezoelectric layer, and
forming the self-assembled monolayer which comprises forming a surface reforming layer by self-assembly, the self-assembled precursor present at a surface of the nozzle plate.

18. The method of claim 15, wherein forming the second electrode layer further comprises:
attaching a protection film on the vibration plate;
dicing the vibration plate to which the protection film is attached; and
removing the protection film.

19. The method of claim 15, wherein forming the self-assembled monolayer comprises:
forming a buffer layer that contacts each surface of the piezoelectric particles; and
forming an overcoat layer on the buffer layer.

20. The method of claim 15, wherein the self-assembled precursor comprises at least one of 1,2-bis(trichlorosilyl)ethane (BTCSE), perfluorodecyltrichlorosilane (FDTS) and/or xylene.
